(19) United States
(12) Patent Application Publication
(10) Pub. No.: US 2026/0175265 A1
(43) Pub. Date: Jun. 25, 2026

(54) CLEANING LIQUID AND METHOD FOR CLEANING SUBSTRATE

(71) Applicant: Tokyo Ohka Kogyo Co., Ltd., Kawasaki-shi (JP)

(72) Inventors: Choitsu Go, Kawasaki-shi (JP); Yukihisa Wada, Kawasaki-shi (JP)

(21) Appl. No.: 19/124,247

(22) PCT Filed: Oct. 27, 2023
(86) PCT No.: PCT/JP2023/038941

§ 371 Date: Apr. 24, 2025

(30) Foreign Application Priority Data
Oct. 31, 2022 (JP) 2022-174693

(51) Int. Cl. B08B 3/02; B08B 3/04; C11D 1/29; C11D 3/34; C11D 17/00; H10P 70/00

(52) U.S. Cl. CPC B08B 3/02; B08B 3/04; C11D 1/29; C11D 3/349; C11D 17/0039; H10P 70/277; C11D 2111/22

(57) ABSTRACT

A cleaning liquid for cleaning a substrate having a metal exposed on a surface, including a basic compound, an amino acid, and water, in which an isoelectric point (pI) of the amino acid and a pH of the cleaning liquid at 23° C. satisfy a condition of Expression (1). The cleaning liquid contains no nitrogen heterocyclic compound, and a concentration of the basic compound is less than 12% by mass with respect to a total mass of the cleaning liquid

$$pI - 2 < pH < pI + 2. \qquad ( 1 )$$

### TECHNICAL FIELD

The present invention relates to a cleaning liquid and a method for cleaning a substrate.

Priority is claimed on Japanese Patent Application No. 2022-174693, filed Oct. 31, 2022, the content of which is incorporated herein by reference.

### BACKGROUND ART

In recent years, in the manufacture of semiconductor devices and liquid crystal display devices, advances in lithography technology have led to rapid miniaturization of wiring patterns. For next-generation semiconductors, ruthenium, tungsten, molybdenum, and the like are being examined as wiring materials for the purpose of reducing resistance.

The wiring process includes, for example, a step of dry-etching a wiring layer using a silicon-based hard mask layer as a mask in order to pattern a wiring for a semi-damascene. Silicon-containing residues derived from a hard mask adhere to a substrate after the dry etching of the wiring layer. These residues are removed by a cleaning treatment.

For example, Patent Document 1 describes, as a cleaning liquid for removing residues after an etching treatment in a wiring process, a residue cleaning liquid for a copper wiring, which is formed of only water and an amino acid having a chelate stability constant of 15 or greater with copper and having no thiol group. The residue cleaning liquid for a copper wiring of Patent Document 1 has been suggested as a cleaning liquid that does not damage a copper wiring.

Non Patent Document 1 describes that a hydrofluoric acid solution, a semi-aqueous alkaline mixture, and the like are tested as a cleaning liquid that removes molybdenum etching residues. Non Patent Document 1 described that the semi-aqueous alkaline mixture exhibits exceptional residue removal performance among the tested substances.

### CITATION LIST

### Patent Document

Patent Document 1: Japanese Patent No. 4375722

### Non Patent Document

Non Patent Document 1: Quoc-Toan Le et al., Wet Cleaning of Molybdenum for Nano Interconnects. ECS Transactions, 108 (4) 39-44 (2022)

### SUMMARY OF INVENTION

### Technical Problem

With the demand for a wiring pattern formed of a low-resistance metal such as ruthenium, tungsten, or molybdenum, there is a demand for development of a cleaning liquid that can be applied to these wiring processes. It is preferable that such a cleaning liquid has exceptional etching residue removal performance and less damage to a metal wiring. However, in the cleaning liquid of the related art, there is a concern about damage to a metal wiring such as a molybdenum wiring.

The present invention has been made in consideration of the above-described circumstances, and an object thereof is to provide a cleaning liquid that can reduce damage to a metal wiring such as molybdenum or tungsten and has favorable cleanability, and a method for cleaning a substrate using the cleaning liquid.

### Solution to Problem

In order to solve the above-described problems, the present invention has employed the following configurations.

According to a first aspect of the present invention, there is provided a cleaning liquid for cleaning a substrate having a metal exposed on a surface, the cleaning liquid including: a basic compound; an amino acid; and water, in which an isoelectric point (pI) of the amino acid and a pH of the cleaning liquid at 23° C. satisfy a condition of Expression (1), pI−2<pH<pI+2 (1), the cleaning liquid contains no nitrogen heterocyclic compound, and a concentration of the basic compound is less than 12% by mass with respect to a total mass of the cleaning liquid.

According to a second aspect of the present invention, there is provided a method for cleaning a substrate, including: a step of cleaning a substrate having a metal exposed on a surface, using the cleaning liquid of the first aspect.

### Advantageous Effects of Invention

According to the present invention, it is possible to provide a cleaning liquid that can reduce damage to a metal wiring such as molybdenum and has favorable cleanability, and a method for cleaning a substrate using the cleaning liquid.

### BRIEF DESCRIPTION OF DRAWINGS

FIG. 1 A view showing an example of a substrate to which a cleaning liquid of one embodiment is applied.

### DESCRIPTION OF EMBODIMENTS

### (Cleaning Liquid)

A cleaning liquid according to a first aspect of the present invention is used for cleaning a substrate having a metal exposed on a surface thereof. The cleaning liquid of the present embodiment contains a basic compound, an amino acid, and water. The pH of the cleaning liquid of the present embodiment at 23° C. and an isoelectric point (pI) of the amino acid at 23° C. satisfy a condition of Expression (1).

$$pI - 2 < pH < pI + 2 \qquad ( 1 )$$

The cleaning liquid of the present embodiment does not contain a nitrogen heterocyclic compound. In the cleaning liquid of the present embodiment, the concentration of the basic compound is less than 12% by mass with respect to the total mass of the cleaning liquid.

### <Basic Compound: Component (B)>

The cleaning liquid of the present embodiment contains a basic compound (hereinafter, also referred to as “component (B)”). The component (B) is not particularly limited as long as the component (B) is a basic compound, but a nitrogen heterocyclic compound is excluded. The nitrogen heterocyclic compound is a compound having an aromatic heterocyclic ring that has a nitrogen atom (nitrogen-containing aromatic heterocyclic ring) and/or an aliphatic heterocyclic ring that has a nitrogen atom (nitrogen-containing aliphatic heterocyclic ring). The nitrogen-containing heterocyclic ring contained in the nitrogen heterocyclic compound may be monocyclic or polycyclic. Specific examples of the nitrogen heterocyclic compound include diazabicycloundecene.

It is preferable that the component (B) is a water-soluble basic compound. The component (B) is more preferably a water-soluble basic compound in which the pH of a 0.01 M aqueous solution is 7.5 or greater, still more preferably a water-soluble basic compound in which the pH of a 0.01 M aqueous solution is 8 or greater, and particularly preferably a water-soluble basic compound in which the pH of a 0.01 M aqueous solution is 8.5 or greater, which is measured by a pH meter at 23° C. The upper limit of the pH is not particularly limited, but is preferably 13 or less and more preferably 12.5 or less. The pH meter is not particularly limited, and a commercially available pH meter may be used. Examples of the pH meter include a portable pH meter (D-73S, manufactured by Horiba, Ltd.).

Examples of the component (B) include a quaternary hydroxide (hereinafter, also referred to as “component (B1)”) and an amine other than the component (B1) (here, a nitrogen-containing heterocyclic compound is excluded)

(hereinafter, also referred to as “component (B2)”).

### <<Quaternary Hydroxide: Component (B1)>>

Examples of the component (B1) include a compound represented by General Formula (b1).

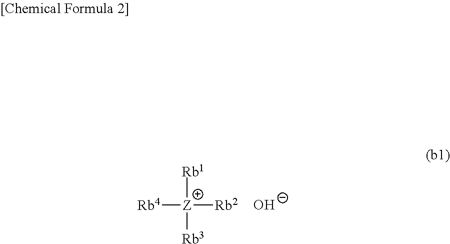

[In the formula, Rb¹ to Rb⁴ each independently represent a hydrocarbon group which may have a substituent; and Z represents a nitrogen atom or a phosphorus atom.]

In Formula (b1), Rb¹ to Rb⁴ each independently represent a hydrocarbon group which may have a substituent.

The hydrocarbon group which may have a substituent as Rb¹ to Rb⁴ may be an aliphatic hydrocarbon group which may have a substituent or an aromatic hydrocarbon group which may have a substituent.

The aliphatic hydrocarbon group as Rb¹ to Rb⁴ may be a saturated aliphatic hydrocarbon group or an unsaturated aliphatic hydrocarbon group. The aliphatic hydrocarbon group may be linear or branched and may have a ring structure.

Examples of the linear aliphatic hydrocarbon group include a linear alkyl group having 1 to 10 carbon atoms, and the linear aliphatic hydrocarbon group has preferably 1 to 8 carbon atoms, more preferably 1 to 6 carbon atoms, still more preferably 1 to 4 carbon atoms or 1 to 3 carbon atoms, and particularly preferably 1 or 2 carbon atoms. Specific examples thereof include a methyl group, an ethyl group, an n-propyl group, an n-butyl group, and an n-pentyl group.

Examples of the branched aliphatic hydrocarbon group include a branched alkyl group having 3 to 10 carbon atoms, and the branched aliphatic hydrocarbon group has preferably 3 to 8 carbon atoms, more preferably 3 to 6 carbon atoms, and still more preferably 3 or 4 carbon atoms. Specific examples thereof include an isopropyl group, an isobutyl group, a tert-butyl group, an isopentyl group, a neopentyl group, a 1,1-diethylpropyl group, and a 2,2-dimethylbutyl group.

The aliphatic hydrocarbon group having a ring structure is an aliphatic hydrocarbon group having an alicyclic group. The alicyclic group may be a monocyclic group or a polycyclic group. In the alicyclic group, some of carbon atoms constituting an aliphatic ring may be substituted with heteroatoms, and examples of the heteroatoms include an oxygen atom and a sulfur atom. Here, the aliphatic hydrocarbon group as Rb¹ to Rb⁴ does not have a nitrogen-containing aliphatic heterocyclic ring.

Examples of the monocyclic aliphatic hydrocarbon groups include a group obtained by removing one hydrogen atom from a monocycloalkane. It is preferable that the monocycloalkane has 3 to 6 carbon atoms. Specific examples of the monocycloalkane include cyclopropane, cyclopentane, and cyclohexane.

Examples of the aliphatic hydrocarbon group of the polycyclic group include a group obtained by removing one hydrogen atom from a polycycloalkane. It is preferable that the polycycloalkane has 7 to 12 carbon atoms.

Specific examples of the polycycloalkane include adamantane, norbornane, isobornane, tricyclodecane, and tetracyclododecane.

The aromatic hydrocarbon group as Rb¹ to Rb⁴ is a hydrocarbon group which has at least one aromatic ring. The aromatic ring is not particularly limited as long as the aromatic ring is a cyclic conjugated system having 4n+2 πelectrons and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms.

Specific examples of the aromatic ring include an aromatic hydrocarbon ring such as benzene, naphthalene, anthracene, or phenanthrene; and an aromatic heterocyclic ring obtained by substituting some carbon atoms constituting the above-described aromatic hydrocarbon ring with heteroatoms. Examples of the heteroatoms in the aromatic heterocyclic ring include an oxygen atom and a sulfur atom. Specific examples of the aromatic heterocyclic ring include a thiophene ring. Here, the aromatic hydrocarbon group as Rb¹ to Rb⁴ does not have a nitrogen-containing aromatic heterocyclic ring.

Specific examples of the aromatic hydrocarbon group include a group (an aryl group or a heteroaryl group) obtained by removing one hydrogen atom from the aromatic hydrocarbon ring or the aromatic heterocyclic ring, a group obtained by removing one hydrogen atom from an aromatic compound (for example, biphenyl or fluorene) having two or more aromatic rings, and a group in which one hydrogen atom of the aromatic hydrocarbon ring or the aromatic heterocyclic ring is substituted with an alkylene group (for example, an arylalkyl group such as a benzyl group, a phenethyl group, a 1-naphthylmethyl group, a 2-naphthylmethyl group, a 1-naphthylethyl group, or a 2-naphthylethyl group).

The alkylene group bonded to the aromatic hydrocarbon ring or the aromatic heterocyclic ring has preferably 1 to 4 carbon atoms, more preferably 1 to 3 carbon atoms, and particularly preferably 1 carbon atom.

The hydrocarbon group as Rb¹ to Rb⁴ may have a substituent. The substituent is not particularly limited, but examples thereof include a hydroxy group.

Rb¹ to Rb⁴ each represent preferably an aliphatic hydrocarbon group which may have a substituent, more preferably a linear or branched alkyl group which may have a substituent, and still more preferably a linear or branched hydroxyalkyl group, a linear or branched hydroxyalkyl group, or a hydrogen atom. The linear hydroxyalkyl group or the linear alkyl group has preferably 1 to 6 carbon atoms, more preferably 1 to 3 carbon atoms, and still more preferably 1 or 2 carbon atoms. The branched hydroxyalkyl group or the linear alkyl group has preferably 3 to 6 carbon atoms and more preferably 3 carbon atoms.

In Formula (b1), Z represents a nitrogen atom or a phosphorus atom.

In a case where the component (B1) is a quaternary amine hydroxide, specific examples thereof include tetraethylammonium hydroxide (TEAH), tetramethylammonium hydroxide (TMAH), tetrapropylammonium hydroxide (TPAH), dimethylbis(2-hydroxyethyl) ammonium hydroxide (DMEMAH), tetrabutylammonium hydroxide (TBAH), tetrapropylammonium hydroxide (TPAH), tris(2-hydroxyethyl)methylammonium hydroxide (THEMAH), choline, dimethyldiethylammonium hydroxide, tetraethanolammonium hydroxide, benzyltrimethylammonium hydroxide, benzyltriethylammonium hydroxide, and benzyltributylammonium hydroxide.

In a case where the (B1) component is a quaternary phosphonium hydroxide, specific examples thereof include tetrabutylphosphonium hydroxide, tetrapropylphosphonium hydroxide, tetraethylphosphonium hydroxide, tetramethylphosphonium hydroxide, tetraphenylphosphonium hydroxide, methyltriphenylphosphonium hydroxide, ethyltriphenylphosphonium hydroxide, propyltriphenylphosphonium hydroxide, butyltriphenylphosphonium hydroxide, benzyltriphenylphosphonium hydroxide, allyltriphenylphosphonium hydroxide, dodecyltriphenylphosphonium hydroxide, tetradecyltriphenylphosphonium hydroxide, hexadecyltriphenylphosphonium hydroxide, and hexadecyltributylphosphonium hydroxide.

The component (B1) is preferably TEAH, TMAH, THEMAH, choline, or tetrabutylphosphonium hydroxide, more preferably TEAH, TMAH, DMEMAH, THEMAH, or choline, and still more preferably TEAH, TMAH, or THEMAH.

<<Amine Other than Component (B1): Component (B2)>>

The component (B2) is an amine that does not correspond to the component (B1) and does not have a nitrogen-containing heterocyclic ring.

Examples of the component (B2) include ammonia, hydroxylamine, a primary monoamine, a secondary monoamine, a tertiary monoamine, a quaternary ammonium salt other than a hydroxide, a diamine, and a polyamine.

Examples of the primary monoamine include alkylamines such as methylamine, ethylamine, propylamine, n-butylamine, isopropylamine, and tert-butylamine; cycloalkylamines such as cyclopentylamine, cyclohexylamine, and cyclohexanemethylamine; alkoxyamines such as methoxyethylamine, methoxypropylamine, methoxybutylamine, ethoxypropylamine, and propoxypropylamine; and alkanol monoamines such as monoethanolamine and monopropanolamine (1-amino-2-propanol and 3-amino-1-propanol), but the present invention is not limited thereto.

Examples of the secondary monoamine include alkylamines such as dimethylamine, diethylamine, methylethylamine, dipropylamine, diisopropylamine, dibutylamine, diisobutylamine, and butylmethylamine; cycloalkylamines such as N,N-dicyclohexylamine and N-cyclopentylcyclohexaneamine; alkoxyamines such as methoxy(methylamine) and N-(2-methoxyethyl)ethylamine; monoalkanol monoamines such as N-methylethanolamine, N-ethylethanolamine, N-propylethanolamine, N-isopropylethanolamine, N-buthylethanolamine, N-isobutylethanolamine, N-methylpropanolamine, N-ethylpropanolamine, N-propylpropanolamine, N-isopropylpropanolamine, N-butylpropanolamine, and N-isobutylpropanolamine; and dialkanol monoamines such as dimethanolamine, diethanolamine, 2-((hydroxymethyl)amino) ethanol, dipropanolamine, diisopropanolamine, and dibutanolamine, but the present invention is not limited thereto.

Examples of the tertiary monoamine include alkylamines such as trimethylamine, triethylamine, tripropylamine, tributylamine, triisobutylamine, dimethylethylamine, dimethylpropylamine, allyldiethylamine, dimethyl-n-butylamine, and diethylisopropylamine; cycloalkylamines such as tricyclopentylamine and tricyclohexylamine; monoalkanol monoamines such as N,N-dimethylethanolamine, N,N-diethylethanolamine, N,N-dipropylethanolamine, N,N-ethylmethylethanolamine, N,N-dimethylpropanolamine, N,N-diethylpropanolamine, N,N-dipropylpropanolamine, and N,N-ethylmethylpropanolamine; dialkanol monoamines such as N-methyldiethanolamine, N-ethyldiethanolamine, N-propyldiethanolamine, N-isopropyldiethanolamine, N-butyldiethanolamine, N-isobutyldiethanolamine, N-methyldipropanolamine, N-ethyldipropanolamine, N-propyldipropanolamine, N-isopropyldipropanolamine, N-butyldipropanolamine, and N-isobutyldipropanolamine; and trialkanol monoamines such as triethanolamine, tripropanolamine, triisopropanolamine, and tributanolamine, but the present invention is not limited thereto.

Examples of the quaternary ammonium salts include quaternary ammonium fluorides, chlorides, bromides, iodides, sulfates, hydrogensulfates, and acetates. Examples of a quaternary ammonium cation include the same cations described as the cation moiety of Formula (b1). Specific examples of the quaternary ammonium salts include tetraethylammonium chloride, tetramethylammonium chloride, tetrapropylammonium chloride, tetrabutylammonium chloride, tetrapropylammonium chloride, tetraethylammonium bromide, tetramethylammonium bromide, tetrapropylammonium bromide, tetrabutylammonium bromide, tetrapropylammonium bromide, tetraethylammonium fluoride, tetramethylammonium fluoride, tetrapropylammonium fluoride, tetrabutylammonium fluoride, tetrapropylammonium fluoride, tetraethylammonium iodide, tetramethylammonium iodide, tetrapropylammonium iodide, tetrabutylammonium iodide, tetrapropylammonium iodide, tetraethylammonium hydrogensulfate, tetramethylammonium hydrogensulfate, tetrapropylammonium hydrogensulfate, tetrabutylammonium hydrogensulfate, and tetrapropylammonium hydrogensulfate, but the present invention is not limited thereto.

The diamine may be any of a primary diamine, a secondary diamine, and a tertiary diamine. Examples of the primary diamine include 2-(2-aminoethylamino) ethanol (AEEA), ethylenediamine, butane-1,4-diamine, 1,3-propanediamine, 1,6-hexanediamine, and pentane-1,5-diamine, but the present invention is not limited thereto. Examples of the secondary diamine include N,N′-dimethylethanediamine, N,N′-dimethylpropanediamine, N,N′-diethyl ethylenediamine, N,N′-diethylpropanediamine, and N,N′-diisopropylethylenediamine, but the present invention is not limited thereto. Examples of the tertiary diamine include N,N,N′,N′-tetramethylethylenediamine, N,N,N′,N′-tetraethylethylenediamine, N,N,N′,N′-tetramethyl-1,3-diaminopropane, N,N,N′,N′-tetramethyl-1,3-diaminobutane, N′,N′-tetramethyl-1,4-diaminobutane, and N,N,N′,N′-tetramethylphenylenediamine, but the present invention is not limited thereto.

The polyamines are compounds including three or more amino groups. The polyamines may include any of a primary amino group, a secondary amino group, and a tertiary amino group. Examples of the polyamine include spermine, spermidine, 3,3′-iminobis(propylamine), N,N-bis(3-aminopropyl)methylamine, N,N-bis(3-aminopropyl)butylamine, N-(3-aminopropyl)-N-dodecylpropane-1,3-diamine, diethylenetriamine, N,N,N′-,N″,N″-pentamethyldiethylenetriamine, and N,N,N′,N″,N″-pentamethyldipropylenetriamine.

The component (B2) may be any of the above-described amines, but is preferably ammonia, hydroxylamine, a primary monoamine, a secondary monoamine, a tertiary monoamine, a quaternary ammonium salt, a diamine, or a polyamine and more preferably ammonia, hydroxylamine, a primary monoamine, or a diamine.

The component (B) is preferably the component (B1), a primary monoamine, a secondary monoamine, a tertiary monoamine, a quaternary ammonium salt, a diamine, or a polyamine, more preferably the component (B1), a quaternary ammonium salt, a diamine, or a polyamine, and particularly preferably the component (B1).

The component (B) is preferably the component (B2), more preferably a primary monoamine, ammonia, hydroxylamine, or a diamine, still more preferably a primary monoamine, ammonia, hydroxylamine, or a primary diamine, and particularly preferably a primary monoamine or hydroxylamine. The primary monoamine is preferably a monoalkanol monoamine and more preferably monoethanolamine.

The component (B) may be used alone or in combination of two or more kinds thereof.

The content of the component (B) in the cleaning liquid of the present embodiment is less than 12% by mass with respect to the total mass of the cleaning liquid. The content of the component (B) is preferably 10% by mass or less, more preferably 8% by mass or less, still more preferably 5% by mass or less, and particularly preferably 3% by mass or less with respect to the total mass of the cleaning liquid. The lower limit of the content of the component (B) is not particularly limited, but may be, for example, 0.0001% by mass or greater, and is preferably 0.001% by mass or greater, more preferably 0.01% by mass or greater, still more preferably 0.05% by mass or greater, and particularly preferably 0.1% by mass or greater or 0.5% by mass or greater with respect to the total mass of the cleaning liquid. In a case where the content of the component (B) is the lower limits or greater of the above-described preferable ranges, the pH of the cleaning liquid is likely to be maintained high. In a case where the content of the component (B) is the upper limits or less of the above-described preferable ranges, anticorrosion properties are likely to be enhanced.

The content of the component (B) in the cleaning liquid of the present embodiment may be, for example, in a range of 0.0001% by mass or greater and less than 12% by mass, and is preferably in a range of 0.001% by mass to 10% by mass, more preferably in a range of 0.01% by mass to 8% by mass, and particularly preferably 0.05% by mass to 5% by mass with respect to the total mass of the cleaning liquid.

The molar concentration of the component (B) in the cleaning liquid of the present embodiment is preferably 1.5 mol/L or less, more preferably 1.0 mol/L or less, still more preferably 0.5 mol/L or less, and particularly preferably 0.1 mol/L or less with respect to the total volume of the cleaning liquid. The lower limit of the molar concentration of the component (B) is not particularly limited, but may be, for example, 0.0001 mol/L or greater, and is preferably 0.001 mol/L or greater and more preferably 0.01 mol/L or greater with respect to the total volume of the cleaning liquid.

The molar concentration of the component (B) in the cleaning liquid of the present embodiment may be, for example, in a range of 0.0001 to 1.5 mol/L and is preferably in a range of 0.001 to 1.0 mol/L and more preferably 0.01 to 0.5 mol/L with respect to the total volume of the cleaning liquid.

The cleaning liquid of the present embodiment may contain any one or both the component (B1) and the component (B2). The cleaning liquid of the present embodiment may contain the component (B1) and may not contain the component (B2), or may contain the component (B2) and may not contain the component (B1). The cleaning liquid of the present embodiment may contain only one kind of the component (B1) and may not contain other components (B1), or may contain two or more kinds of the components (B1). The cleaning liquid of the embodiment may contain only one kind of the component (B2) and may not contain other components (B2) or may contain two or more kinds of the components (B2).

The cleaning liquid of the present embodiment may not contain, for example, one or more selected from the group consisting of a primary monoamine, a secondary monoamine, a tertiary monoamine, a quaternary ammonium salt, a diamine, and a polyamine. The cleaning liquid of the present embodiment may not contain, for example, one or more of the basic compounds described above as the specific examples. The cleaning liquid of the present embodiment may not contain, for example, one or more selected from the group consisting of a primary alkanol monoamine, a secondary alkanol monoamine, a tertiary alkanol monoamine, a primary aromatic monoamine, a secondary aromatic monoamine, a tertiary aromatic monoamine, a quaternary aromatic ammonium salt, a primary aminophenol, a secondary aminophenol, a tertiary aminophenol, an aromatic diamine, and an aromatic polyamine. The cleaning liquid of the present embodiment may contain one kind of the component (B) selected from the group consisting of monoethanolamine, ammonia, hydroxylamine, and 2-(2-aminoethylamino) ethanol, and may not contain other basic compounds. For example, the cleaning liquid of the present embodiment may not contain one or more selected from the group consisting of ammonia, 2-hydroxyethyltrimethylammonium hydroxide, tetrabutylammonium hydroxide, 2-amino-2-methyl-1-propanol, diethanolamine, trishydroxymethylaminomethane, dimethylbis(2-hydroxyethyl) ammonium hydroxide, and 2-(2-aminoethoxy) ethanol.

### <Chelating Agent: Component (A)>

The cleaning liquid of the present embodiment contains an amino acid (hereinafter, also referred to as “component (A1)”) as a chelating agent.

### <<Amino Acid: Component (A1)>>

Examples of the component (A1) include alanine (isoelectric point: 6.00), arginine (isoelectric point: 10.76), asparagine (isoelectric point: 5.41), cysteine (isoelectric point: 5.07), glutamine (isoelectric point: 5.65), glycine (isoelectric point: 5.97), histidine (isoelectric point: 7.59), isoleucine (isoelectric point: 5.97), leucine (isoelectric point: 5.98), lysine (isoelectric point: 9.74), ornithine (isoelectric point: 9.70), methionine (isoelectric point: 5.74), phenylalanine (isoelectric point: 5.48), (isoelectric point: 5.97), serine (isoelectric point: 5.68), threonine (isoelectric point: 5.60), tryptophan (isoelectric point: 5.89), tyrosine (isoelectric point: 5.66), and valine (isoelectric point: 5.96).

As the component (A1), a neutral amino acid or a basic amino acid is preferable, and a basic amino acid is more preferable. Examples of the neutral amino acid include alanine, asparagine, cysteine, glutamine, glycine, isoleucine, leucine, methionine, phenylalanine, serine, threonine, tryptophan, tyrosine, and valine. Examples of the basic amino acid include arginine, histidine, lysine, and ornithine. Among these, arginine or lysine is preferable, and arginine is more preferable.

From the viewpoint of the relationship with the pH of the cleaning liquid described below, the amino acid has an isoelectric point of preferably 5 or greater, more preferably 7 or greater, still more preferably 8 or greater, and particularly preferably 9 or greater. The isoelectric point of the amino acid is preferably in a range of 5 to 13, more preferably in a range of 8.5 to 13, still more preferably in a range of 9 to 11, and particularly preferably in a range of 10 to 11.

The component (A1) may be used alone or in combination of two or more kinds thereof.

The content of the component (A1) may be, for example, 0.0001% by mass or greater, and preferably 0.001% by mass or greater, more preferably 0.005% by mass or greater, still more preferably 0.01% by mass or greater, and particularly preferably 0.02% by mass or greater with respect to the total mass of the cleaning liquid. In a case where the content of the component (A1) is the lower limits or greater of the above-described preferable ranges, the anticorrosion properties of the cleaning liquid are likely to be improved.

The content of the component (A1) is preferably 5% by mass or less, more preferably 4% by mass or less, still more preferably 3% by mass or less, even more preferably 1% by mass or less, and particularly preferably 0.5% by mass or less with respect to the total mass of the cleaning liquid. In a case where the content of the component (A1) is the upper limits or less of the above-described preferable ranges, the balance between the component (A1) and other components is likely to be achieved.

The content of the component (A1) in the cleaning liquid of the present embodiment may be, for example, in a range of 0.0001% by mass to 5% by mass, and is preferably in a range of 0.001% by mass to 3% by mass, more preferably in a range of 0.005% by mass to 1% by mass, and particularly preferably in a range of 0.01% by mass to 0.5% by mass with respect to the total mass of the cleaning liquid.

The cleaning agent of the present embodiment may contain no amino acid other than a basic amino acid or may contain no acidic amino acid and/or no neutral amino acid. The cleaning liquid of the present embodiment may contain one kind of amino acid selected from the group consisting of arginine, lysine, and histidine, and may not contain other amino acids.

<<Chelating Agent Other than Component (A1): Component (A2)>>

The cleaning liquid of the present embodiment may contain a chelating agent other than the component (A1) (hereinafter, referred to as “component (A2)”).

The component (A2) is not particularly limited as long as the component (A2) is a compound having a function of chelating with a metal. Examples of the component (A2) include a compound having a coordinating group coordinated to a metal. Examples of the coordinating group include an acidic group. Examples of the acidic group include a carboxy group, a phosphonic acid group, a sulfo group, and a phenolic hydroxy group.

Examples of the component (A2) include a carboxylic acid-based chelating agent, a phosphonic acid-based chelating agent, and an inorganic chelating agent.

### Carboxylic Acid-Based Chelating Agent:

The carboxylic acid-based chelating agent is a chelating agent containing a carboxy group as a coordinating group in a molecule. Examples of the carboxylic acid-based chelating agent include an aminopolycarboxylic acid-based chelating agent, a hydroxycarboxylic acid-based chelating agent, and an aliphatic carboxylic acid-based chelating agent.

Examples of the aminopolycarboxylic acid-based chelating agent include butylenediamine tetracetic acid, diethylenetriaminepentaacetic acid (DTPA), ethylenediaminetetrapropionic acid, triethylenetetraminehexacetic acid, 1,3-diamino-2-hydroxypropan-N,N,N′,N′-tetraacetic acid, propylenediaminetetraacetic acid, ethylenediaminetetraacetic acid (EDTA), trans-1,2-diaminocyclohexanetetraacetic acid, ethylenediaminediacetic acid, ethylenediaminedipropionic acid, 1,6-hexamethylene-diamine-N,N,N′,N′-tetraacetic acid, N,N-bis(2-hydroxybenzyl)ethylenediamine-N,N-diacetic acid, diaminopropanetetraacetic acid, 1,4,7,10-tetraazacyclododecanetetraacetic acid, diaminopropanoltetraacetic acid, (hydroxyethyl)ethylenediaminetrisacetic acid, and iminodiacetic acid (IDA).

Examples of the hydroxycarboxylic acid-based chelating agent include malic acid, citric acid, glycolic acid, gluconic acid, heptonic acid, tartaric acid, and lactic acid.

Examples of the aliphatic carboxylic acid-based chelating agent include oxalic acid, malonic acid, succinic acid, glutaric acid, adipic acid, pimelic acid, sebacic acid, and maleic acid.

### Phosphonic Acid-Based Chelating Agent:

The phosphonic acid-based chelating agent is a chelating agent containing at least one phosphonic acid group in a molecule. Examples of the phosphonic acid-based chelating agent include ethylaminobis(methylenephosphonic acid), dodecylaminobis(methylenephosphonic acid), nitrilotris(methylenephosphonic acid) (NTPO), ethylenediaminebis(methylenephosphonic acid) (EDDPO), 1,3-propylenediaminebis(methylenephosphonic acid), ethylenediaminetetra(methylenephosphonic acid) (EDTPO), ethylenediaminetetra(ethylenephosphonic acid), 1,3-propylenediaminetetra(methylenephosphonic acid) (PDTMP), 1,2-diaminopropanetetra(methylenephosphonic acid), 1,6-hexamethylenediaminetetra(methylenephosphonic acid), diethylenetriaminepenta(methylenephosphonic acid) (DEPPO), diethylenetriaminepenta (ethylenephosphonic acid), triethylenetetraminehexa(methylenephosphonic acid), and triethylenetetraminehexa (ethylenephosphonic acid).

### Inorganic Chelating Agent:

Examples of the inorganic chelating agent include condensed phosphoric acid and a salt thereof. Examples of the inorganic chelating agent include pyrrolic acid and a salt thereof, metaphosphoric acid and a salt thereof, tripolyphosphoric acid and a salt thereof, and hexametaphosphoric acid and a salt thereof.

The cleaning agent of the present embodiment may or may not contain the component (A2). The cleaning agent of the present embodiment may or may not include one or more selected from the group consisting of an aminopolycarboxylic acid-based chelating agent, a hydroxycarboxylic acid-based chelating agent, an aliphatic carboxylic acid-based chelating agent, a phosphonic acid-based chelating agent, and an inorganic chelating agent. The cleaning agent of the present embodiment may or may not include one or more of the compounds described above as the specific examples of the component (A2). The cleaning agent of the present embodiment may not contain tartaric acid and iminodiacetic acid.

### <Water: Component (D)>

The cleaning liquid of the present embodiment contains water as a solvent. Water may contain a trace amount of components that are unavoidably mixed. The water used in the cleaning liquid of the present embodiment is preferably water that has been subjected to a purification treatment, such as distilled water, ion exchange water, and ultrapure water, and ultrapure water generally used in the production of a semiconductor is more preferably used.

The content of water in the cleaning liquid of the present embodiment is not particularly limited, and the amount of water to be required to adjust the concentration of each component to a desired concentration can be used.

### <Optional Components>

The cleaning liquid of the present embodiment may contain optional components in addition to the component (B), the component (A), and the component (D). Examples of the optional components include an organic solvent, a surfactant, a pH adjuster, and an anticorrosive agent.

### <<Organic Solvent: (S)>>

The cleaning liquid according to the present embodiment may contain an organic solvent within a range where the effects of the present invention are not impaired. A water-soluble organic solvent is preferable as the organic solvent. Examples of the water-soluble organic solvent include alcohols (such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, 2-methyl-2,4-pentanediol, and 3-methoxy-3-methyl-1-butanol), dimethyl sulfoxide, ethers (such as ethylene glycol dimethyl ether, diethylene glycol dimethyl ether, triethylene glycol dimethyl ether, tetraethylene glycol dimethyl ether, propylene glycol dimethyl ether), and morpholines (such as N-methylmorpholine N-oxide).

The organic solvent is preferably alcohols, more preferably a polyhydric alcohol, still more preferably glycols, and particularly preferably ethylene glycol.

The organic solvent may be used alone or in combination of two or more kinds thereof.

In a case where the cleaning liquid of the present embodiment contains an organic solvent, the content of the organic solvent is preferably 90% by mass or less and more preferably 80% by mass or less with respect to the total amount of the amount of water and the amount of the organic solvent. In a case where the cleaning liquid according to the present embodiment contains an organic solvent, the content of the organic solvent is preferably in a range of 1% to 90% by mass, more preferably in a range of 10% to 90% by mass, still more preferably in a range 50% to 90% by mass, and particularly preferably in a range of 70% to 80% by mass with respect to the total mass of the cleaning liquid.

The cleaning liquid of the present embodiment may or may not contain an organic solvent. The cleaning liquid of the present embodiment may or may not contain one or more of the compounds described above as the specific examples of the organic solvent.

### <<pH Adjuster: (C)>>

The cleaning liquid according to the present embodiment may contain a pH adjuster in order to adjust the pH of the cleaning liquid. Examples of the pH adjuster include an acidic compound.

The acidic compound may be an inorganic acid or an organic acid.

Examples of the inorganic acid include hydrochloric acid, sulfuric acid, sulfurous acid, nitric acid, nitrous acid, phosphoric acid, boric acid, and hexafluorophosphoric acid. The acidic compound may be a salt of an inorganic acid. Examples of the salt of an inorganic acid include an ammonium salt of an inorganic acid. Examples of the ammonium salt of an inorganic acid include ammonium chloride, ammonium sulfate, ammonium sulfite, ammonium nitrate, ammonium nitrite, ammonium phosphate, ammonium borate, and ammonium hexafluorophosphate.

Examples of the organic acid include aliphatic carboxylic acids such as formic acid, acetic acid, propionic acid, butyric acid, lactic acid, oxalic acid, tartaric acid, and citric acid. The aliphatic carboxylic acid may be used as the component (A2).

The pH adjuster may be used alone or in combination of two or more kinds thereof.

As the pH adjuster, the amount thereof to be required to adjust the pH of the cleaning liquid to a desired pH can be used. In a case where the cleaning liquid of the present embodiment contains a pH adjuster, the content of the pH adjuster may be, for example, in a range of 0.03% to 10% by mass with respect to the total mass of the cleaning liquid.

The cleaning liquid of the present embodiment may or may not contain a pH adjuster. The cleaning liquid of the present embodiment may or may not contain one or more of the compounds described above as the specific examples of the pH adjuster.

### <<Surfactant>

The cleaning liquid of the present embodiment may contain a surfactant, for example, for the purpose of adjusting the wettability of the cleaning liquid to a substrate. Examples of the surfactant include a nonionic surfactant, an anionic surfactant, a cationic surfactant, and an amphoteric surfactant.

Examples of the nonionic surfactant include polyalkylene oxide alkylphenyl ether-based surfactants, polyalkylene oxide alkyl ether-based surfactants, block polymer-based surfactants consisting of polyethylene oxide and polypropylene oxide, polyoxyalkylene distyrenated phenyl ether-based surfactants, polyalkylene tribenzylphenyl ether-based surfactants, and acetylene polyalkylene oxide-based surfactants.

Examples of the anionic surfactant include alkylsulfonic acids, alkylbenzenesulfonic acids, alkylnaphthalenesulfonic acids, alkyldiphenyl ether sulfonic acids, fatty acid amidosulfonic acids, polyoxyethylene alkyl ether carboxylic acids, polyoxyethylene alkyl ether acetic acids, polyoxyethylene alkyl ether propionic acids, alkyl phosphonic acids, and fatty acid salts. Examples of “salts” include ammonium salts, sodium salts, potassium salts, and tetramethylammonium salts.

Examples of the cationic surfactant include alkylpyridium-based surfactants. A quaternary ammonium salt-based surfactant may be used as the component (B2).

Examples of the amphoteric surfactant include betaine type surfactants, amino acid type surfactants, imidazoline type surfactants, and amine oxide type surfactants.

These surfactants are generally commercially available. The surfactant may be used alone or in combination of two or more kinds thereof.

In a case where the cleaning liquid of the present embodiment contains the surfactant, the content of the surfactant is not particularly limited, but is, for example, preferably in a range of 0.0001% by mass to 5% by mass, more preferably in a range of 0.0002% by mass to 3% by mass, still more preferably in a range of 0.002% by mass to 1% by mass, and particularly preferably in a range of 0.002% by mass to 0.2% by mass with respect to the total mass of the cleaning liquid. In a case where the content of the surfactant is in the above-described preferable ranges, bubbles generated by the foaming agent are likely to be dense.

The cleaning liquid of the present embodiment may or may not contain a surfactant. The cleaning liquid of the present embodiment may or may not contain one or more selected from the group consisting of nonionic surfactants, anionic surfactants, cationic surfactants, and amphoteric surfactants. The cleaning liquid of the present embodiment may or may not contain one or more of the above-described compounds described as the specific examples of the surfactant.

### <<Anticorrosive Agent>>

The cleaning liquid of the present embodiment may contain an anticorrosive agent.

In addition, examples of the anticorrosive agent include ascorbic acids such as ascorbic acid, ascorbic acid phosphate ester, and ascorbic acid sulfate ester; catechols such as pyrocatechol, 4-tert-butylcatechol, pyrogallol, gallic acid, methyl gallate, 1,2,4-benzenetriol, and tiron; saccharides such as fructose, glucose and ribose; and polycarboxylic acids such as polyacrylic acid, polymaleic acid, and copolymers thereof.

The anticorrosive agent may be used alone or in combination of two or more kinds thereof.

In a case where the cleaning liquid of the present embodiment contains an anticorrosive agent, the content of the anticorrosive agent is not particularly limited, but is preferably 0.0001% by mass to 0.2% by mass, more preferably 0.0003% by mass to 0.1% by mass, still more preferably 0.0005% by mass to 0.05% by mass, and particularly preferably 0.01% by mass to 0.03% by mass with respect to the total mass of the cleaning liquid.

The cleaning liquid of the present embodiment may not contain one or more selected from the group consisting of ascorbic acids, catechols, saccharides, and polycarboxylic acids, and may not contain one or more of the compounds described above as the specific examples of the anticorrosive agent. The cleaning liquid of the present embodiment may not contain the anticorrosive agent.

### <<Buffer>>

The cleaning liquid according to the present embodiment may contain a buffer. The buffer is a compound having an action of suppressing a change in the pH of a solution.

The buffer is not particularly limited as long as the buffer is a compound having a pH buffering ability. As the buffer, for example, a compound with a pKa of 6 to 11 can be used.

Examples of the buffer include a Good's buffer. Example of the Good's buffer include 2-cyclohexylaminoethanesulfonic acid (CHES), 3-cyclohexylaminopropanesulfonic acid (CAPS), N-tris(hydroxymethyl)methyl-3-aminopropanesulfonic acid (TAPS), 4-(cyclohexylamino)-1-butanesulfonic acid (CABS), tricine, bicine, 2-morpholinoethanesulfonic acid monohydrate (MES), bis(2-hydroxyethyl)aminotris(hydroxymethyl) methane (Bis-Tris), N-(2-acetamido)iminodiacetic acid (ADA), piperazine-1,4-bis(2-ethanesulfonic acid) (PIPES), N-(2-acetamido)-2-aminoethanesulfonic acid (ACES), 2-hydroxy-3-morpholinopropanesulfonic acid (MOPSO), N,N-bis(2-hydroxyethyl)-2-aminoethanesulfonic acid (BES), 3-morpholinopropanesulfonic acid (MOPS), N-tris(hydroxymethyl)methyl-2-aminoethanesulfonic acid (TES), 2-[4-(2-hydroxyethyl)-1-piperazinyl]ethanesulfonic acid (HEPES), 3-[N-tris(hydroxymethyl)methylamino]-2-hydroxypropanesulfonic acid (TAPSO), piperazine-1,4-bis(2-hydroxypropanesulfonic acid) (POPSO), 4-(2-hydroxyethyl) piperazine-1-(2-hydroxypropane-3-sulfonic acid) (HEPSO), and 4-(2-hydroxyethyl)-1-piperazinepropanesulfonic acid (EPPS).

The buffer may be used alone or in combination of two or more kinds thereof.

In a case where the cleaning liquid of the present embodiment contains the buffer, the content of the buffer is not particularly limited, but may be 0.001% by mass to 10% by mass, and is preferably 0.005% by mass to 5% by mass, more preferably 0.01% by mass to 1% by mass, and particularly preferably 0.05% by mass to 0.5% by mass, or 0.05% by mass to 0.3% by mass, with respect to the total mass of the cleaning liquid.

The cleaning liquid of the present embodiment may or may not contain a buffer.

The cleaning liquid of the present embodiment may or may not contain one or more of the above-described compounds described as the specific examples of the buffer.

### <<Impurities and the Like>>

The cleaning liquid of the present embodiment may contain metal impurities including metal atoms such as a Fe atom, a Cr atom, a Ni atom, a Zn atom, a Ca atom, and a Pb atom. The total content of the metal atoms in the cleaning liquid of the present embodiment is preferably 100 ppt by mass or less with respect to the total mass of the cleaning liquid. The lower limit of the total content of the metal atoms is preferably as low as possible, but may be, for example, 0.001 ppt by mass or greater. The total content of the metal atoms may be, for example, 0.001 ppt by mass to 100 ppt by mass. In a case where the total content of the metal atoms is set to be the upper limits or less of the above-described preferable ranges, the defect suppressing properties and the residue suppressing properties of the cleaning liquid are improved. It is considered that in a case where the total content of the metal atoms is set to be the lower limits or greater of the above-described preferable ranges, the metal atoms are unlikely to be present in a state of being released in the system and unlikely to adversely affect the production yield of the entire cleaning target.

The content of the metal impurities can be adjusted, for example, by a purification treatment such as filtering. The purification treatment such as filtering may be performed on a part or all of the raw materials before the cleaning liquid is prepared, or may be performed after the cleaning liquid is prepared.

The cleaning liquid of the present embodiment may include, for example, organic substance-derived impurities (organic impurities). The total content of the organic impurities in the cleaning liquid of the present embodiment is preferably 5,000 ppm by mass or less. The lower limit of the content of the organic impurities is preferably as low as possible, and the lower limit may be, for example, 0.1 ppm by mass or greater. The total content of the organic impurities may be, for example, in a range of 0.1 ppm by mass to 5,000 ppm by mass.

The cleaning liquid of the present embodiment may include, for example, an object to be counted with a size counted by a light scattering type in-liquid particle counter. The size of the object to be counted is, for example, 0.04 μm or greater. The number of the objects to be counted in the cleaning liquid of the present embodiment is, for example, 1,000 or less per mL of the cleaning liquid, and the lower limit is, for example, 1 or greater. It is considered that in a case where the number of the objects to be counted in the cleaning liquid is in the above-described ranges, the metal corrosion suppressing effect of the cleaning liquid is improved.

The organic impurities and/or the objects to be counted may be added to the cleaning liquid or may be unavoidably mixed into the cleaning liquid during a step of producing the cleaning liquid. Examples of the cases where organic impurities are unavoidably mixed during the step of producing the cleaning liquid include a case where organic impurities are contained in raw materials (for example, an organic solvent) used in the production of the cleaning liquid, and a case where organic impurities are mixed (for example, contamination) from the external environment during the step of producing the cleaning liquid, but the present invention is not limited thereto.

In a case where the objects to be counted are added to the cleaning liquid, the abundance ratio may be adjusted for each specific size in consideration of the surface roughness and the like of a cleaning target.

<pH>

From the viewpoint of the cleanability, the pH of the cleaning liquid of the present embodiment is preferably 8 or greater. The pH of the cleaning liquid of the present embodiment is more preferably 9 or greater, still more preferably 9.5 or greater, and particularly preferably 10 or greater. From the viewpoint of anticorrosion properties, the pH of the cleaning liquid of the present embodiment is preferably 13 or less, more preferably 12.5 or less, and still more preferably 12 or less. The pH of the cleaning liquid of the present embodiment may be, for example, in a range of 8 to 13, preferably in a range of 9 to 13, still more preferably in a range of 9 to 12, and particularly preferably in a range of 10 to 12.

The pH value is a value measured with a pH meter under conditions of a normal temperature (23° C.) and a normal pressure (1 atm). Examples of the pH meter include a portable pH meter (D-73S, manufactured by Horiba, Ltd.).

In the cleaning liquid of the present embodiment, the isoelectric point (pI) of the amino acid which is the component (A1) and the pH of the cleaning liquid at 23° C. satisfy Expression (1).

$$pI - 2 < pH < pI + 2 \qquad ( 1 )$$

In a case where the pH of the cleaning liquid and the isoelectric point of the component (A1) satisfy the relationship of Expression (1), the anticorrosion properties with respect to a metal wiring such as molybdenum can be enhanced while favorable cleanability is maintained.

### <Storage Container>

A method of storing the cleaning liquid of the present embodiment is not particularly limited, and storage containers known in the related art can be used. In order to ensure the stability of the cleaning liquid, a void ratio in a container in a case of storing the cleaning liquid in the container and/or a type of gas filling the voids may be appropriately set. For example, the void ratio in the storage container may be approximately in a range of 0.01% to 30% by volume.

In a case of using the cleaning liquid of the present embodiment, the cleaning liquid may be diluted to 2 to 2,000 times to obtain a diluent, and then a cleaning step may be performed using the diluent.

In one embodiment, the cleaning liquid of the present embodiment does not contain one or more selected from the group consisting of an inorganic alkali compound, a hydroxycarboxylic acid, an aminopolycarboxylic acid, polyphosphonic acid, an acidic amino acid (such as glutamic acid or aspartic acid), alkylene glycol, a fatty acid, phosphonic acid, sulfuric acid ester, alkenyl succinic acid, an organic acid, a water-soluble polymer, N,N,N′,N″,N″-pentamethyldiethylenetriamine, ethylene amines, an aliphatic polycarboxylic acid, oxalic acid, a non-phenolic organic acid, and phenol.

### <Substrate:

The substrate to which the cleaning liquid of the present embodiment is applied is a substrate having a metal exposed on a surface thereof. Examples of the metal include copper, cobalt, titanium, tantalum, ruthenium, molybdenum, tungsten, and aluminum. Among these, copper, cobalt, molybdenum, or tungsten is preferable, and molybdenum or tungsten is more preferable. The metal may be in the form of an oxide, a carbide, or a nitride, and examples thereof include aluminum oxide, tungsten carbide, titanium nitride, tantalum nitride, and aluminum nitride.

It is preferable that the substrate includes a metal-containing layer that contains a metal. The metal contained in the metal-containing layer may be a simple substance, an alloy, or a compound. Examples of the compound of the metal include an oxide, a nitride, an oxynitride, and a carbide. The content of the metal in the metal-containing layer is preferably 20% by mass or greater, more preferably 50% by mass or greater, still more preferably 80% by mass or greater, and may be 100% by mass with respect to the total mass of the composition forming the metal-containing layer. The metal-containing layer can be formed by a known method, and for example, CVD, ALD, or PVD can be used.

It is preferable that the metal-containing layer is a wiring layer. The metal-containing layer may be, for example, a molybdenum wiring layer or a tungsten wiring layer. The cleaning liquid of the present embodiment may be used, for example, for cleaning the substrate after dry etching of the metal-containing layer. More specifically, the cleaning liquid of the present embodiment may be used for cleaning the substrate after dry etching of the metal wiring layer (a molybdenum wiring layer, a tungsten wiring layer, or the like).

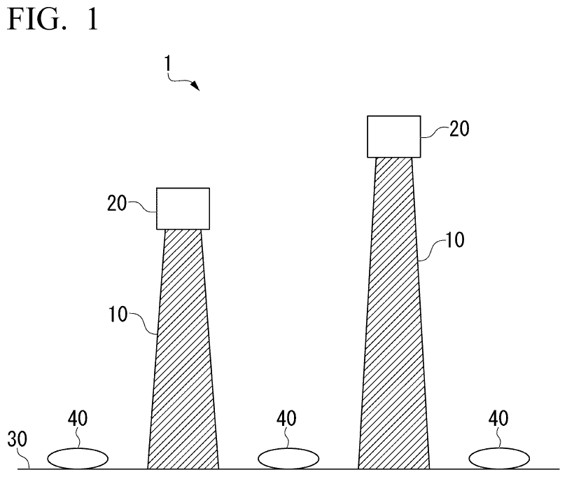

FIG. 1 shows an example of the substrate to which the cleaning liquid of the present embodiment is applied. A substrate 1 shown in FIG. 1 is, for example, a substrate after dry etching is performed on the wiring layer. In the substrate 1, a wiring layer 10 is formed on a dielectric layer 30, and a hard mask layer 20 is formed on the wiring layer 10. The substrate 1 is a substrate after dry etching is performed on the wiring layer 10 using the hard mask layer 20 as a mask. A residue 40 which is a dry etching residue adheres to the substrate 1.

In the substrate 1, the wiring layer 10 is a metal wiring layer. The hard mask layer 20 is, for example, formed of silicon dioxide (SiO₂) or silicon nitride (SiN). The residue 40 includes a molybdenum oxide or a tungsten oxide, and a silicon-containing residue.

In a case where the substrate 1 is cleaned with a cleaning liquid of the related art, the metal contained in the wiring layer 10 is corroded due to the contact with the cleaning liquid. Therefore, the metal wiring is damaged by the cleaning treatment.

Meanwhile, the cleaning liquid of the present embodiment contains the component (A1), and thus the metal is protected. In addition, the cleaning liquid contains the component (B) so that the silicon-containing residue 40 can be favorably cleaned. Therefore, the residue 40 can be cleaned while the wiring layer 10 containing a metal (molybdenum, tungsten, or the like) is protected.

Since the cleaning liquid of the present embodiment contains the basic compound (B) and the amino acid (A1), and the isoelectric point of the component (A1) and the pH of the cleaning liquid at 23° C. satisfy the conditions of Expression (1), silicon-containing residues can be favorably cleaned while a metal (molybdenum, tungsten, or the like) is protected in the substrate having the metal exposed on the surface thereof. Therefore, the cleaning liquid of the present embodiment can be suitably applied to cleaning of a substrate after dry etching of a metal wiring layer (a molybdenum wiring layer, a tungsten wiring layer, or the like).

Further, since the cleaning liquid of the present embodiment does not contain a nitrogen heterocyclic compound and the concentration of the component (B) is less than 12% by mass, the anticorrosion effect of the component (A1) can be sufficiently obtained.

### (Method for Cleaning Substrate)

A method for cleaning a substrate according to a second aspect includes a step of cleaning a substrate using the cleaning liquid according to the first aspect. The substrate is a substrate having a metal exposed on a surface thereof. Examples of the metal include copper, cobalt, titanium, tantalum, ruthenium, molybdenum, and tungsten. Among these, copper, cobalt, molybdenum, or tungsten is preferable, and molybdenum or tungsten is more preferable. The metal may be in the form of an oxide, a carbide, or a nitride, and examples thereof include aluminum oxide, tungsten carbide, titanium nitride, tantalum nitride, and aluminum nitride.

### <Step of Cleaning Substrate: Cleaning Step>

The present step is a step of etching a substrate using the treatment liquid according to the first aspect. The present step includes an operation of bringing the cleaning liquid into contact with the substrate. A method for the cleaning method is not particularly limited, and a known cleaning method can be used. Examples of such a method include a method of continuously coating a substrate rotating at a constant speed with a cleaning liquid (rotation coating method), a method of immersing a substrate in a cleaning liquid for a certain period of time (dipping method), and a method of spraying a cleaning liquid onto a surface of a substrate (spraying method).

The cleaning step may be performed only once or two or more times. In a case of performing cleaning two or more times, the same cleaning method may be repeatedly performed, or a combination of different cleaning methods may be performed.

The temperature at which the cleaning treatment is performed is not particularly limited. The temperature for the cleaning treatment may be, for example, 15° C. to 70° C., 20° C. to 70° C., 30° C. to 65° C., or 40° C. to 65° C. The cleaning performance is improved by raising the temperature of the treatment liquid, but the temperature of the cleaning liquid can be appropriately selected in consideration of suppression of a change in the composition of the cleaning liquid, the workability, the safety, the cost, and the like.

As the cleaning time, a time sufficient for removing impurities, residues, and the like from a surface of the substrate can be appropriately selected. Examples of the cleaning time include 10 seconds to 30 minutes, 20 seconds to 15 minutes, 30 seconds to 10 minutes, or 30 seconds to 5 minutes.

The cleaning liquid according to the first aspect may be diluted to 2 to 2,000 times to obtain a diluent at the time of use. In the present step, the substrate may be cleaned using the diluent.

### <Substrate>

Examples of the substrate as a cleaning target include the same substrates as those described as a target to which the cleaning liquid according to the first aspect is applied. The substrate may be a substrate (for example, FIG. 1) after dry etching of a layer containing a metal (molybdenum, tungsten, or the like) is performed by a wiring process. The substrate may be a substrate after dry etching of the wiring layer is performed in, for example, a semi-damascene process. In addition, the substrate may be a substrate having a metal (molybdenum, tungsten, or the like) exposed after dry etching a Si-containing layer (for example, a Si-containing insulating film) in a wiring process. In addition, the substrate may be a substrate having a metal (molybdenum, tungsten, or the like) exposed after a CMP step in the wiring process. In particular, in a case where a CMP slurry includes a Si-based filler, cleaning with the cleaning liquid according to the first aspect is useful.

### <Optional Step>

The method of the present embodiment may include optional steps in addition to the cleaning step. Examples of the optional step include a hard mask layer etching step, a dry etching step of a wiring layer, a chemical mechanical polishing (CMP) step, and a contact etching step.

### (Hard Mask Layer Etching Step)

The method of the present embodiment may include a hard mask layer etching step prior to the cleaning step. The hard mask layer etching step is a step of etching a hard mask layer. Examples of the material for the hard mask layer include silicon dioxide (SiO₂), silicon nitride (Si₃N₄), and silicon oxynitride (SiON). Examples of the method for forming a hard mask layer include CVD, ALD, and PVD.

Etching of the hard mask layer can be performed using, for example, a resist pattern as a mask. Etching of the hard mask layer can be performed, for example, by dry etching. Examples of the etching gas include a mixture of an oxygen gas and a halogen-based gas. Examples of the halogen-containing gas include fluorocarbon-based gases such as a tetrafluoromethane (CF₄) gas and a trifluoromethane (CHF₃) gas; and chlorine-based gases such as a chlorine (Cl₂) gas.

### (Wiring Layer Dry-Etching Step)

The method of the present embodiment may include a wiring layer dry-etching step prior to the cleaning step. The wiring layer dry-etching step is a step of dry-etching the wiring layer. In the method of the present embodiment, the wiring layer contains at least one metal selected from the group consisting of molybdenum and tungsten. Examples of a method for forming the wiring layer include CVD, ALD, and PVD.

Etching of the wiring layer can be performed using, for example, a hard mask pattern obtained by transferring a resist pattern as a mask. Dry etching of the wiring layer can be performed using, for example, an oxygen gas, a chlorine gas, or the like as an etching gas.

### (Cmp Step)

The method of the present embodiment may include a CMP step. The CMP step is a step of performing a CMP treatment on a substrate. By performing the CMP step, a surface of the substrate is flattened. The CMP step can be performed in order to flatten the wiring layer after formation of a liner layer and a wiring layer on the substrate.

For example, a Low-k layer is formed on a substrate, and a trench and a via are formed on the Low-k layer. Next, a liner layer is formed, and then a wiring layer is formed. Then, the surface of the substrate is flattened by CMP. Scrapings including an oxide of a metal derived from the wiring layer and the like adhere to the substrate after the CMP, but the scrapings can be removed while corrosion is suppressed by performing the cleaning step.

### (Contact and Via Forming Step)

The method of the present embodiment may include a Si-based insulating film dry-etching step for forming a contact hole or a via prior to the cleaning step. The Si-based insulating film is formed of a film containing Si, such as a SiO₂ film, SiOC film, SiC film, or SiN film. In addition, the etch stop layer containing SiN, SiCN, SiCO, Al₂O₃, or the like may be formed under the Si-based insulating film that forms a contact or a via. After the dry etching, a metal wiring (a molybdenum wiring, a tungsten wiring, or the like) is exposed on the contact or the via bottom. Examples of a method for forming the wiring layer include CVD, ALD, and PVD.

In addition to the steps, the method of the present embodiment may include a hard mask removing step, a dielectric layer forming step, a polishing step, an etch stop layer forming step, and the like after the cleaning step.

According to the method of the present embodiment, since the substrate is cleaned with the cleaning liquid according to the first aspect, silicon-containing etching residues and the like can be cleaned without damaging a metal in a substrate having the metal exposed on a surface. Therefore, the method of the present embodiment can be suitably applied to a substrate after dry etching of a metal-containing layer (for example, a tungsten wiring layer or a molybdenum wiring layer) is performed in a wiring process.

### EXAMPLES

Hereinafter, the present invention will be described in more detail based on examples, but the present invention is not limited to these examples.

### <Preparation of Cleaning Liquid>

### Examples 1 to 24 and Comparative Examples 1 to 29

Each component listed in Tables 1 to 20 was mixed to prepare a cleaning liquid of each example.

TABLE 1

| | Component | Component | Component | Component | Component | | |
|---|---|---|---|---|---|---|---|
| | (B) | (A1) | (S) | (C) | (D) | pH | pH-pI |
| Comparative | TMAH | — | — | — | Water | 13.05 | — |
| Example 1 | [0.912] | | | | [Remainder] | | |
| | (0.1) | | | | | | |
| Comparative | TMAH | Arg | — | — | Water | 13.04 | 2.28 |
| Example 2 | [0.912] | [0.02] | | | [Remainder] | | |
| | (0.1) | | | | | | |

TABLE 2

| | Component | Component | Component | Component | Component | | |
|---|---|---|---|---|---|---|---|
| | (B) | (A1) | (S) | (C) | (D) | pH | pH-pI |
| Comparative | TMAH | — | — | — | Water | 12.08 | — |
| Example 3 | [0.091] | | | | [Remainder] | | |
| | (0.01) | | | | | | |
| Example 1 | TMAH | Arg | — | — | Water | 12.09 | 1.33 |
| | [0.091] | [0.02] | | | [Remainder] | | |
| | (0.01) | | | | | | |

TABLE 3

| | Component | Component | Component | Component | Component | | |
|---|---|---|---|---|---|---|---|
| | (B) | (A1) | (S) | (C) | (D) | pH | pH-pI |
| Comparative | MEA | — | — | CA | Water | 10.03 | — |
| Example 4 | [0.061] | | | [Appropriate | [Remainder] | | |
| | (0.01) | | | amount] | | | |
| Example 2 | MEA | Arg | — | CA | Water | 10.05 | −0.71 |
| | [0.061] | [0.02] | | [Appropriate | [Remainder] | | |
| | (0.01) | | | amount] | | | |

TABLE 4

| | Component | Component | Component | Component | Component | | |
|---|---|---|---|---|---|---|---|
| | (B) | (A1) | (S) | (C) | (D) | pH | pH-pI |
| Comparative | MEA | — | — | CA | Water | 9.02 | — |
| Example 5 | [0.061] | | | [Appropriate | [Remainder] | | |
| | (0.01) | | | amount] | | | |
| Example 3 | MEA | Arg | — | CA | Water | 8.98 | −1.78 |
| | [0.061] | [0.02] | | [Appropriate | [Remainder] | | |
| | (0.01) | | | amount] | | | |

TABLE 5

| | Component | Component | Component | Component | Component | | |
|---|---|---|---|---|---|---|---|
| | (B) | (A1) | (S) | (C) | (D) | pH | pH-pI |
| Comparative | MEA | — | — | CA | Water | 7.92 | — |
| Example 6 | [0.061] | | | [Appropriate | [Remainder] | | |
| | (0.01) | | | amount] | | | |
| Comparative | MEA | Arg | — | CA | Component | 7.97 | −2.79 |
| Example 7 | [0.061] | [0.02] | | [Appropriate | (D) | | |
| | (0.01) | | | amount] | [Remainder] | | |

TABLE 6

| | Component | Component | Component | Component | Component | | |
|---|---|---|---|---|---|---|---|
| | (B) | (A1) | (S) | (C) | (D) | pH | pH-pI |
| Comparative | MEA | — | — | — | Water | 10.67 | — |
| Example 8 | [0.061] | | | | [Remainder] | | |
| | (0.01) | | | | | | |
| Example 4 | MEA | Arg | — | — | Water | 10.76 | 0 |
| | [0.061] | [0.005] | | | [Remainder] | | |
| | (0.01) | | | | | | |
| Example 5 | MEA | Arg | — | — | Water | 10.69 | −0.07 |
| | [0.061] | [0.02] | | | [Remainder] | | |
| | (0.01) | | | | | | |
| Example 6 | MEA | Arg | — | — | Water | 10.87 | 0.11 |
| | [0.061] | [0.05] | | | [Remainder] | | |
| | (0.01) | | | | | | |
| Example 7 | MEA | Arg | — | — | Water | 10.65 | −0.11 |
| | [0.061] | [0.1] | | | [Remainder] | | |
| | (0.01) | | | | | | |
| Example 8 | MEA | Lys | — | — | Water | 10.68 | 0.94 |
| | [0.061] | [0.01] | | | [Remainder] | | |
| | (0.01) | | | | | | |
| Example 9 | MEA | Lys | — | — | Water | 10.53 | 0.79 |
| | [0.061] | [0.02] | | | [Remainder] | | |
| | (0.01) | | | | | | |
| Example 10 | MEA | Lys | — | — | Water | 10.46 | −0.30 |
| | [0.061] | [0.05] | | | [Remainder] | | |
| | (0.01) | | | | | | |
| Example 11 | MEA | Lys | — | — | Water | 10.34 | −0.42 |
| | [0.061] | [0.1] | | | [Remainder] | | |
| | (0.01) | | | | | | |

TABLE 7

| | Component | Component | Component | Component | Component | | |
|---|---|---|---|---|---|---|---|
| | (B) | (A1) | (S) | (C) | (D) | pH | pH-pI |
| Comparative | MEA | — | — | — | Water | 11.31 | — |
| Example 9 | [0.611] | | | | [Remainder] | | |
| | (0.1) | | | | | | |
| Example 12 | MEA | Arg | — | — | Water | 11.24 | 0.48 |
| | [0.611] | [0.1] | | | [Remainder] | | |
| | (0.1) | | | | | | |
| Example 13 | MEA | Arg | — | — | Water | 11.33 | 0.57 |
| | [0.611] | [0.5] | | | [Remainder] | | |
| | (0.1) | | | | | | |

TABLE 8

| | Component | Component | Component | Component | Component | | |
|---|---|---|---|---|---|---|---|
| | (B) | (A1) | (S) | (C) | (D) | pH | pH-pI |
| Comparative | MEA | — | — | — | Water | 11.68 | — |
| Example 10 | [3.055] | | | | [Remainder] | | |
| | (0.5) | | | | | | |
| Example 14 | MEA | Arg | — | — | Water | 11.64 | 0.88 |
| | [3.055] | [0.02] | | | [Remainder] | | |
| | (0.5) | | | | | | |
| Example 15 | MEA | Arg | — | — | Water | 11.68 | 0.92 |
| | [3.055] | [0.1] | | | [Remainder] | | |
| | (0.5) | | | | | | |
| Example 16 | MEA | Arg | — | — | Water | 11.61 | 0.85 |
| | [3.055] | [0.5] | | | [Remainder] | | |
| | (0.5) | | | | | | |
| Comparative | MEA | Gly | — | — | Water | 10.02 | 4.05 |
| Example 11 | [0.061] | [0.02] | | | [Remainder] | | |
| | (0.01) | | | | | | |
| Comparative | MEA | Cys | — | — | Water | 10.19 | 5.12 |
| Example 12 | [0.061] | [0.02] | | | [Remainder] | | |
| | (0.01) | | | | | | |
| Comparative | MEA | His | — | — | Water | 10.39 | 2.8 |
| Example 13 | [0.061] | [0.02] | | | [Remainder] | | |
| | (0.01) | | | | | | |

TABLE 9

| | Component | Component | Component | Component | Component | | |
|---|---|---|---|---|---|---|---|
| | (B) | (A1) | (S) | (C) | (D) | pH | pH-pI |
| Comparative | AEEA | — | — | — | Water | 10.82 | — |
| Example 14 | [0.104] | | | | [Remainder] | | |
| | (0.01) | | | | | | |
| Example 17 | AEEA | Arg | — | — | Water | 10.85 | 0.09 |
| | [0.104] | [0.02] | | | [Remainder] | | |
| | (0.01) | | | | | | |

TABLE 10

| | Component | Component | Component | Component | Component | | |
|---|---|---|---|---|---|---|---|
| | (B) | (A1) | (S) | (C) | (D) | pH | pH-pI |
| Comparative | NH₂OH | — | — | — | Water | 8.93 | — |
| Example 15 | [0.033] | | | | [Remainder] | | |
| | (0.01) | | | | | | |
| Example 18 | NH₂OH | Arg | — | — | Water | 9.95 | −0.81 |
| | [0.033] | [0.02] | | | [Remainder] | | |
| | (0.01) | | | | | | |

TABLE 11

| | Component | Component | Component | Component | Component | | |
|---|---|---|---|---|---|---|---|
| | (B) | (A1) | (S) | (C) | (D) | pH | pH-pI |
| Comparative | NH₃ | — | — | — | Water | 10.64 | — |
| Example 16 | [0.017] | | | | [Remainder] | | |
| | (0.01) | | | | | | |
| Example 19 | NH₃ | Arg | — | — | Water | 10.62 | −0.14 |
| | [0.017] | [0.02] | | | [Remainder] | | |
| | (0.01) | | | | | | |

TABLE 12

| | Component | Component | Component | Component | Component | | |
|---|---|---|---|---|---|---|---|
| | (B) | (A1) | (S) | (C) | (D) | pH | pH-pI |
| Comparative | MEA | — | EG | — | Water | 10.72 | — |
| Example 17 | [0.061] | | [10] | | [Remainder] | | |
| | (0.01) | | | | | | |
| Example 20 | MEA | Arg | EG | — | Water | 10.71 | −0.05 |
| | [0.061] | [0.02] | [10] | | [Remainder] | | |
| | (0.01) | | | | | | |

TABLE 13

| | Component | Component | Component | Component | Component | | |
|---|---|---|---|---|---|---|---|
| | (B) | (A1) | (S) | (C) | (D) | pH | pH-pI |
| Comparative | MEA | — | EG | — | Water | 10.38 | — |
| Example 18 | [0.061] | | [50] | | [Remainder] | | |
| | (0.01) | | | | | | |
| Example 21 | MEA | Arg | EG | — | Water | 10.38 | −0.38 |
| | [0.061] | [0.02] | [50] | | [Remainder] | | |
| | (0.01) | | | | | | |

TABLE 14

| | Component | Component | Component | Component | Component | | |
|---|---|---|---|---|---|---|---|
| | (B) | (A1) | (S) | (C) | (D) | pH | pH-pI |
| Comparative | MEA | — | EG | — | Water | 10.25 | — |
| Example 19 | [0.061] | | [80] | | [Remainder] | | |
| | (0.01) | | | | | | |
| Example 22 | MEA | Arg | EG | — | Water | 10.27 | −0.49 |
| | [0.061] | [0.02] | [80] | | [Remainder] | | |
| | (0.01) | | | | | | |

TABLE 15

| | Component | Component | Component | Component | Component | | |
|---|---|---|---|---|---|---|---|
| | (B) | (A1) | (S) | (C) | (D) | pH | pH-pI |
| Comparative | DBU | — | — | — | Water | 11.16 | — |
| Example 20 | [0.152] | | | | [Remainder] | | |
| | (0.01) | | | | | | |
| Comparative | DBU | Lys | — | — | Water | 10.98 | 1.24 |
| Example 21 | [0.152] | [0.02] | | | [Remainder] | | |
| | (0.01) | | | | | | |

TABLE 16

| | Component | Component | Component | Component | Component | | |
|---|---|---|---|---|---|---|---|
| | (B) | (A1) | (S) | (C) | (D) | pH | pH-pI |
| Comparative | MEA | — | — | — | Water | 11.76 | — |
| Example 22 | [5] | | | | [Remainder] | | |
| | (0.82) | | | | | | |
| Example 23 | MEA | Arg | — | — | Water | 11.71 | 0.95 |
| | [5] | [0.02] | | | [Remainder] | | |
| | (0.82) | | | | | | |

TABLE 17

| | Component | Component | Component | Component | Component | | |
|---|---|---|---|---|---|---|---|
| | (B) | (A1) | (S) | (C) | (D) | pH | pH-pI |
| Comparative | MEA | — | — | — | Water | 11.92 | — |
| Example 23 | [8] | | | | [Remainder] | | |
| | (1.31) | | | | | | |
| Example 24 | MEA | Arg | — | — | Water | 11.9 | 1.14 |
| | [8] | [0.02] | | | [Remainder] | | |
| | (1.31) | | | | | | |

TABLE 18

| | Component | Component | Component | Component | Component | | |
|---|---|---|---|---|---|---|---|
| | (B) | (A1) | (S) | (C) | (D) | pH | pH-pI |
| Comparative | MEA | — | — | — | Water | 11.96 | — |
| Example 24 | [12] | | | | [Remainder] | | |
| | (1.97) | | | | | | |
| Comparative | MEA | Arg | — | — | Water | 11.96 | 1.2 |
| Example 25 | [12] | [0.02] | | | [Remainder] | | |
| | (1.97) | | | | | | |

TABLE 19

| | Component | Component | Component | Component | Component | | |
|---|---|---|---|---|---|---|---|
| | (B) | (A1) | (S) | (C) | (D) | pH | pH-pI |
| Comparative | MEA | — | — | — | Water | 12.08 | — |
| Example 26 | [15] | | | | [Remainder] | | |
| | (2.46) | | | | | | |
| Comparative | MEA | Arg | — | — | Water | 12.09 | 1.33 |
| Example 27 | [15] | [0.02] | | | [Remainder] | | |
| | (2.46) | | | | | | |

TABLE 20

| | Component | Component | Component | Component | Component | Component | |
|---|---|---|---|---|---|---|---|
| | (B) | (A1) | (A2) | (S) | (C) | (D) | pH |
| Comparative | MEA | — | — | — | — | Water | 10.67 |
| Example 8 | [0.061] | | | | | [Remainder] | |
| | (0.01) | | | | | | |
| Comparative | MEA | — | TA | — | — | Water | 9.80 |
| Example 28 | [0.061] | | [0.02] | | | [Remainder] | |
| | (0.01) | | | | | | |
| Comparative | MEA | — | IDA | — | — | Water | 9.74 |
| Example 29 | [0.061] | | [0.02] | | | [Remainder] | |
| | (0.01) | | | | | | |

In Tables 1 to 20, each abbreviation has the following meaning. The numerical values in the brackets show the mass percentage with respect to the total mass of the cleaning liquid. The numerical values in parentheses in the component (B) denote the molar concentration (mol/L) of the component (B) in the cleaning liquid. [Appropriate amount] in the component (C) denotes the amount added for adjusting the pH of the cleaning liquid to a predetermined pH.

The term “pH” denotes the pH of the cleaning liquid at 23° C. The pH was measured using a pH meter (portable pH meter D-73S, manufactured by Horiba, Ltd.).

“pH-pl” denotes the numerical value obtained by subtracting the isoelectric point (pI) of the component (A1) from the pH of the cleaning liquid at 23° C.

As is clear from the pH of the cleaning liquid listed in Tables 2 to 17, the cleaning liquids of Examples 1 to 24 all satisfy the relationship of Expression (1) between the pH of the cleaning liquid and the isoelectric point (pI) of the component (A1).

### <Basic Compound: Component (B)>

TMAH: tetramethylammonium hydroxide
MEA: monoethanolamine
AEEA: 2-(2-aminoethylamino) ethanol
NH₂OH: hydroxylamine
NH₃: ammonia
DBU: diazabicycloundecene

### <Amino Acid: Component (A1)>

Arg: arginine (isoelectric point: 10.76)
Lys: lysine (isoelectric point: 9.74)
Gly: glycine (isoelectric point: 5.97)
Cys: cysteine (isoelectric point: 5.07)
His: histidine (isoelectric point: 7.59)

### <Chelating Agent: Component (A2)>

TA: tartaric acid
IDA: iminodiacetic acid

### <Solvent: Component(S)>

EG: ethylene glycol

### <pH Adjuster>

CA: Citric acid

### [Evaluation of Anticorrosion Performance]

The anticorrosion performance of the cleaning liquid with respect to the metal wiring was evaluated by an etching rate with respect to molybdenum.

### <Measurement of Molybdenum Etching Rate>

A substrate on which a molybdenum film (50 nm) was formed on a 12-inch silicon substrate by a PVD method was used as the substrate. The substrate was cut into 2 cm×2 cm to produce a wafer coupon. A 200 ml beaker was filled with 100 mL of the cleaning liquid of each example and heated to 60° C., and the wafer coupon was immersed in the cleaning liquid. The mixture was stirred at 60° C. and 300 rpm during the immersion of the wafer coupon. After the immersion for 10 minutes, the wafer coupon was taken out from the cleaning liquid, cleaned with water at room temperature for 30 seconds, and dried by blowing nitrogen.

The film thicknesses of the wafer coupon before and after the immersion in the cleaning liquid were measured. A fluorescence X-ray device (ZSX Primus IV, manufactured by Rigaku Corporation) was used for the measurement of the film thickness. The etching rate was calculated from a change in the film thickness of the molybdenum film before and after the cleaning treatment. The results are listed in the columns of “MoER” in Tables 21 to 40.

### <Evaluation of Anticorrosion Performance>

The anticorrosion performance by the component (A1) or the component (A2) was evaluated with reference to the molybdenum etching rate (Mo ER₀) of comparative examples (reference comparative examples) in which the component (A1) and the component (A2) were not added. The reference comparative examples of each example are described in the top row of each table. A value obtained by dividing the molybdenum etching rate (Mo ER) of each example by the molybdenum etching rate (Mo ER₀) of the reference comparative example was calculated, and the results are listed in the columns of “Mo ER/Mo ER₀” in Tables 21 to 40.

The anticorrosion performance was evaluated according to the following evaluation criteria. The results are listed in the columns of “anticorrosion performance” in Tables 21 to 40.

### Evaluation Criteria

A: Mo ER/Mo ER₀ was less than 0.5, and Mo ER was less than 2 Å/min.
D: Mo ER/Mo ER₀ was 0.5 or greater, or Mo ER was 2 Å/min or greater.

### [Evaluation of Cleaning Performance]

The cleaning performance of the cleaning liquid was evaluated by an etching rate with respect to amorphous silicon. Silicon is a component contained in residues after metal wiring dry etching.

### <Measurement of Amorphous Silicon Etching Rate>

A substrate on which an amorphous silicon film (100 nm) was formed on a 12-inch silicon substrate by a PVD method was used as the substrate. The substrate was cut into 2 cm×2 cm to produce a wafer coupon. A 200 mL beaker was filled with 100 mL of the cleaning liquid of each example and heated to 60° C., and the wafer coupon was immersed in the cleaning liquid. The mixture was stirred at 60° C. and 300 rpm during the immersion of the wafer coupon. After the immersion for 10 minutes, the wafer coupon was taken out from the cleaning liquid, cleaned with water at room temperature for 30 seconds, and dried by blowing nitrogen.

The film thicknesses of the wafer coupon before and after the immersion in the cleaning liquid were measured. An ellipsometer (M-2000, manufactured by J. A. Woolam) was used for measuring the film thickness. The etching rate (aSi ER) was calculated from a change in the film thickness of the amorphous silicon film before and after the cleaning treatment.

### <Evaluation of Cleaning Performance>

The change rate (CR) of the amorphous silicon etching rate (aSi ER) of each example with respect to the amorphous silicon etching rate (aSi ER₀) of the reference comparative example described in the top row of each table was calculated according to the following equation.

$$CR ( \% ) = [ aSi {ER}_{0} - asi ER ] / aSi {ER}_{0} \times 100$$

The cleaning performance was evaluated according to the following evaluation criteria. The results are listed in the columns of “cleaning performance” in Tables 21 to 40.

### Evaluation Criteria

A: aSi ER was 30 nm/min or greater.
B: aSi ER was 10 nm/min or greater and less than 30 nm/min.
C: aSi ER was less than 10 nm/min, and CR was less than 10%.
D: aSi ER was less than 10 nm/min, and CR was 10% or greater.

TABLE 21

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 6.54 | — | — | — |
| Example 1 | | | | | |
| Comparative | 60 | 2.77 | 0.42 | D | A |
| Example 2 | | | | | |

TABLE 22

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 5.59 | — | — | — |
| Example 3 | | | | | |
| Example 1 | 60 | 1.26 | 0.22 | A | A |

TABLE 23

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 2.60 | — | — | — |
| Example 4 | | | | | |
| Example 2 | 60 | 0.72 | 0.28 | A | B |

TABLE 24

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 1.77 | — | — | — |
| Example 5 | | | | | |
| Example 3 | 60 | 0.51 | 0.29 | A | C |

TABLE 25

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 0.73 | — | — | — |
| Example 6 | | | | | |
| Comparative | 60 | 0.61 | 0.84 | D | D |
| Example 7 | | | | | |

TABLE 26

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 2.88 | — | — | — |
| Example 8 | | | | | |
| Example 4 | 60 | 1.41 | 0.49 | A | A |
| Example 5 | 60 | 0.51 | 0.22 | A | A |
| Example 6 | 60 | 0.84 | 0.29 | A | A |
| Example 7 | 60 | 0.37 | 0.13 | A | A |
| Example 8 | 60 | 1.24 | 0.43 | A | A |
| Example 9 | 60 | 0.81 | 0.28 | A | A |
| Example 10 | 60 | 0.62 | 0.21 | A | A |
| Example 11 | 60 | 0.76 | 0.26 | A | A |

TABLE 27

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 2.67 | — | — | — |
| Example 9 | | | | | |
| Example 12 | 60 | 1.22 | 0.46 | A | A |
| Example 13 | 60 | 0.02 | 0.01 | A | A |

TABLE 28

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 2.22 | — | — | — |
| Example 10 | | | | | |
| Example 14 | 60 | 0.48 | 0.21 | A | A |
| Example 15 | 60 | 0.71 | 0.32 | A | A |
| Example 16 | 60 | 0.95 | 0.43 | A | A |
| Comparative | 60 | 1.47 | 0.51 | D | B |
| Example 11 | | | | | |
| Comparative | 60 | 1.54 | 0.53 | D | B |
| Example 12 | | | | | |
| Comparative | 60 | 1.98 | 0.69 | D | A |
| Example 13 | | | | | |

TABLE 29

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 6.14 | — | — | — |
| Example 14 | | | | | |
| Example 17 | 60 | 1.19 | 0.19 | A | A |

TABLE 30

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 2.20 | — | — | — |
| Example 15 | | | | | |
| Example 18 | 60 | 0.80 | 0.36 | A | B |

TABLE 31

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 6.01 | — | — | — |
| Example 16 | | | | | |
| Example 19 | 60 | 1.25 | 0.21 | A | A |

TABLE 32

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 3.24 | — | — | — |
| Example 17 | | | | | |
| Example 20 | 60 | 1.38 | 0.42 | A | A |

TABLE 33

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 2.21 | — | — | — |
| Example 18 | | | | | |
| Example 21 | 60 | 0.98 | 0.44 | A | B |

TABLE 34

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 0.43 | — | — | — |
| Example 19 | | | | | |
| Example 22 | 60 | 0.11 | 0.26 | A | B |

TABLE 35

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 1.81 | — | — | — |
| Example 20 | | | | | |
| Comparative | 60 | 1.41 | 0.78 | D | B |
| Example 21 | | | | | |

TABLE 36

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 1.95 | — | — | — |
| Example 22 | | | | | |
| Example 23 | 60 | 0.62 | 0.32 | A | A |

TABLE 37

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 1.49 | — | — | — |
| Example 23 | | | | | |
| Example 24 | 60 | 0.65 | 0.44 | A | A |

TABLE 38

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 0.54 | — | — | — |
| Example 24 | | | | | |
| Comparative | 60 | 0.79 | 1.46 | D | A |
| Example 25 | | | | | |

TABLE 39

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 1.50 | — | — | — |
| Example 26 | | | | | |
| Comparative | 60 | 1.65 | 1.10 | D | A |
| Example 27 | | | | | |

TABLE 40

| | Treatment | | | | |
|---|---|---|---|---|---|
| | temper- | | | Anti- | |
| | ature | Mo ER | Mo ER/ | corrosion | Cleaning |
| | [° C.] | [Å/min] | Mo ER₀ | performance | performance |
| Comparative | 60 | 2.88 | — | — | — |
| Example 8 | | | | | |
| Comparative | 60 | 1.67 | 0.58 | D | — |
| Example 28 | | | | | |
| Comparative | 60 | 1.81 | 1.08 | D | — |
| Example 29 | | | | | |

As shown in the results of Tables 21 to 40, in the cleaning liquids of Examples 1 to 24, the anticorrosion performance was remarkably improved while the cleaning performance was favorably maintained, as compared with the reference comparative examples. Conversely, in the comparative examples, the anticorrosion performance was not sufficiently improved as compared with the reference comparative examples.

As shown in these results, it was confirmed that the cleaning liquids of Examples 1 to 24 satisfying the relationship of Expression (1) could favorably clean the dry etching residues while suppressing damage to the metal wiring.

As shown in the results of Comparative Examples 20 and 21, it was confirmed that in a case where the cleaning liquid contained a nitrogen heterocyclic compound, the anticorrosion effect due to the component (A1) was not sufficiently exhibited.

As shown in the results of Comparative Examples 24 to 27, it was confirmed that in a case where the content of the component (B) was 12% by mass or greater, the anticorrosion effect of the component (A1) was not sufficiently exhibited.

While preferred examples of the present invention have been described and illustrated above, it should be understood that these are exemplary of the present invention and are not to be considered as limiting. Additions, omissions, substitutions, and other modifications can be made without departing from the scope of the present invention. Accordingly, the present invention is not limited by the description above but by the scope of the appended claims.

### REFERENCE SIGNS LIST

1 Substrate
10 Wiring layer
20 Hard mask layer
30 Low-k layer
40 Residue

What is claimed is:

1. A cleaning liquid for cleaning a substrate having a metal exposed on a surface, the cleaning liquid comprising:
a basic compound;
an amino acid; and
water,
wherein an isoelectric point (pI) of the amino acid and a pH of the cleaning liquid at 23° C. satisfy a condition of Expression (1),
$$pI - 2 < pH < pI + 2 , \qquad ( 1 )$$
the cleaning liquid contains no nitrogen heterocyclic compound, and
a concentration of the basic compound is less than 12% by mass with respect to a total mass of the cleaning liquid.

2. The cleaning liquid according to claim 1, wherein a pH of the basic compound at 23° C. in a 0.01 M aqueous solution is 7.5 or greater.

3. The cleaning liquid according to claim 1, wherein the amino acid has an isoelectric point of 7 or higher.

4. The cleaning liquid according to claim 1, wherein the pH of the cleaning liquid at 23° C. is 9 or greater.

5. The cleaning liquid according to claim 1, wherein the concentration of the basic compound is 1% by mass or less with respect to the total mass of the cleaning liquid.

6. The cleaning liquid according to claim 1, wherein a concentration of the amino acid is 0.5% by mass or less with respect to the total mass of the cleaning liquid.

7. The cleaning liquid according to claim 1, further comprising at least one selected from the group consisting of a buffer, an anticorrosive agent, a surfactant, and an organic solvent.

8. The cleaning liquid according to claim 1, wherein the substrate is a substrate after dry etching or chemical mechanical polishing (CMP) is performed on the metal.

9. The cleaning liquid according to claim 1, wherein the metal is molybdenum or tungsten.

10. A method for cleaning a substrate, comprising cleaning a substrate having a metal exposed on a surface using the cleaning liquid according to claim 1.

11. The method for cleaning a substrate according to claim 10, wherein the substrate is a substrate after dry etching or chemical mechanical polishing (CMP) is performed on the metal.

12. The method for cleaning a substrate according to claim 10, wherein the metal is molybdenum or tungsten.
